(19) United States
(12) Patent Application Publication
(10) Pub. No.: US 2023/0010077 A1
(43) Pub. Date: Jan. 12, 2023

(54) METHOD OF MANUFACTURING SEMICONDUCTOR DEVICE AND SEMICONDUCTOR DEVICE

(71) Applicant: ABLIC Inc., Tokyo (JP)

(72) Inventors: Riki NAGASAWA, Tokyo (JP); Hiroaki TAKASU, Tokyo (JP); Osamu KARIKOME, Tokyo (JP)

(21) Appl. No.: 17/804,169

(22) Filed: May 26, 2022

(30) Foreign Application Priority Data
Jul. 6, 2021 (JP) 2021-111910

(51) Int. Cl. H01L 21/02

(52) U.S. Cl. CPC H01L 21/0217; H01L 21/02472

(57) ABSTRACT

A method of manufacturing a semiconductor device includes: forming a base oxide film on a surface of a silicon semiconductor substrate (P-type well region); forming a thick film portion provided along a boundary C between an activation region A and an element isolation region B and having at least a predetermined width W from the boundary C toward the element isolation region B and a thin film portion having a film thickness smaller than a film thickness tₐ of the thick film portion in the activation region A and the element isolation region B other than the thick film portion on the base oxide film; forming a silicon nitride film on surfaces of the thick film portion and the thin film portion; and selectively removing the silicon nitride film in the element isolation region B through an over-etching process.

### CROSS-REFERENCE TO RELATED APPLICATIONS

This application claims the benefit of Japanese Application No. 2021-111910, filed Jul. 6, 2021, the entire disclosure of which is hereby incorporated herein by reference.

### TECHNICAL FIELD

The present invention relates to a method of manufacturing a semiconductor device and a semiconductor device.

### BACKGROUND ART

In a semiconductor device having a plurality of semiconductor elements, an element isolation structure is provided such that the elements do not electrically interfere with each other. As a method of providing this element isolation structure, there is, for example, a local oxidation of silicon (LOCOS) method of isolating a plurality of elements to be formed in an activation region by selectively forming a thick silicon oxide film (also referred to as a “field oxide film” in some cases) in an element isolation region (also referred to as a “field” in some cases).

As an example of the LOCOS method, first, a silicon nitride film through which an oxidizing species hardly passes and which is hard to thermally oxidize sufficiently compared with silicon is formed on a silicon semiconductor substrate. Before forming the silicon nitride film, a base oxide film is formed as a stress buffer film between the silicon semiconductor substrate and the silicon nitride film. The silicon nitride film is then selectively removed through an etching process to form a mask pattern, and then a field oxidation process is performed. An element isolation structure is therefore provided with a field oxide film formed by oxidizing and thickening a surface of the silicon semiconductor substrate not covered with the silicon nitride film, and thus a plurality of elements are electrically isolated.

In the field oxidation process, since the oxidizing species diffuses from an opening of the mask pattern to under the silicon nitride film through the base oxide film, a structure in which a peripheral edge of the field oxide film enters under the silicon nitride film is obtained. A sectional shape at the peripheral edge of the field oxide film is like a bird's beak, and is thus sometimes referred to as “bird's beak”. Since the bird's beak enters the activation region, an effective area of the activation region may be narrowed, and further, electrical characteristics may be adversely affected.

With a manner of making the base oxide film as thin as possible in order to prevent the oxidizing species from diffusing into the silicon semiconductor substrate under the silicon nitride film, the bird's beak is reduced to secure a large effective area of the activation region, and more semiconductor elements can be disposed.

If the base oxide film is thinned, a dislocation tends to occur in the silicon semiconductor substrate due to shear stress generated between the base oxide film and the silicon nitride film. The occurrence of the dislocation may lead to deterioration in characteristics due to hot carriers, and a durable period (device life) may be considerably reduced.

For the purpose of relaxing the shear stress, for example, a method of forming a field oxide film having a film thickness of 400 nm or more by setting a film thickness of a base oxide film to 10 nm to 100 nm and setting a heating temperature of heat treatment performed on the base oxide film to 1,050° C. or more has been proposed (refer to Japanese Patent Application Laid-open Publication No. 05-21424).

In a case where the base oxide film is thinned, the method of manufacturing a semiconductor device disclosed in JP-A-5-21424 solves the problem that the durability is reduced by dislocation due to stress, but in addition, in a case where the silicon nitride film is selectively removed through a dry etching process, a minute hole called a micro-trench may be formed.

In this dry etching process, specifically, if high-frequency power is applied to an etching gas such as SF₆ to generate ions and radicals to selectively remove the silicon nitride film, particularly highly reactive radicals tend to accumulate in the vicinity of a peripheral edge of an etching surface. As a result, a micro-trench accompanied by a defect is formed in the surrounding silicon, or even if the micro-trench is not formed, a defect may be generated in the silicon due to etching damage. If the silicon semiconductor substrate is field-oxidized in such a state, defects of silicon remain along with deformation of the field oxide film or bird's beak, and a desired electrical characteristic cannot be obtained in a semiconductor element formed in an activation region due to generation of a leakage current through the defects in some cases.

In one aspect of the present invention, it is therefore provided a method of manufacturing a semiconductor device capable of forming a semiconductor element that can easily obtain desired electrical characteristics by suppressing of the occurrence of large deformation or defects of a field oxide film and a bird's beak thereof even if a base oxide film is thinned in order to reduce the bird's beak.

According to one aspect of the present invention, there is provided a method of manufacturing a semiconductor device in which an activation region for forming semiconductor elements and an element isolation region for electrically isolating the semiconductor elements are provided, the method including:
forming a base oxide film on a surface of a silicon semiconductor substrate;
forming a thick film portion provided along a boundary between the activation region and the element isolation region and having at least a predetermined width from the boundary toward the element isolation region and a thin film portion thinner than the thick film portion in the activation region and the element isolation region other than the thick film portion on the base oxide film;
forming a silicon nitride film on surfaces of the thick film portion and the thin film portion;
selectively removing the silicon nitride film in the element isolation region through an over-etching process; and
selectively forming a field oxide film on the surface of the silicon semiconductor substrate in the element isolation region through a field oxidation process using the silicon nitride film in the activation region as a mask.

According to one aspect of the present invention, it is possible to provide a method of manufacturing a semiconductor device capable of forming a semiconductor element that can easily obtain desired electrical characteristics by suppressing of large deformation or defects of a field oxide film and a bird's beak thereof even if a base oxide film is thinned in order to reduce the bird's beak.

### BRIEF DESCRIPTION OF DRAWINGS

FIG. 1 is a schematic sectional view illustrating a method of manufacturing a semiconductor device according to a first embodiment.

FIG. 2 is a schematic sectional view illustrating a method of manufacturing a semiconductor device according to the first embodiment.

FIG. 3 is a schematic sectional view illustrating a method of manufacturing a semiconductor device according to the first embodiment.

FIG. 4 is a schematic sectional view illustrating a method of manufacturing a semiconductor device according to the first embodiment.

FIG. 5 is a schematic sectional view illustrating a method of manufacturing a semiconductor device according to the first embodiment.

FIG. 6 is a schematic sectional view illustrating a method of manufacturing a semiconductor device according to a second embodiment.

FIG. 7 is a schematic sectional view illustrating a method of manufacturing a semiconductor device according to a third embodiment.

FIG. 8 is a schematic sectional view illustrating a method of manufacturing a semiconductor device of the related art.

FIG. 9 is a schematic sectional view illustrating a method of manufacturing a semiconductor device of the related art.

FIG. 10 is a schematic sectional view illustrating a method of manufacturing a semiconductor device of the related art.

FIG. 11 is a schematic sectional view illustrating a method of manufacturing a semiconductor device of the related art.

FIG. 12 is a schematic sectional view illustrating another method of manufacturing a semiconductor device of the related art.

FIG. 13 is a schematic sectional view illustrating another semiconductor device of the related art.

### DESCRIPTION OF EMBODIMENTS

A method of manufacturing a semiconductor device according to an embodiment of the present invention is a method of manufacturing a semiconductor device in which an activation region for forming semiconductor elements and an element isolation region for electrically isolating the semiconductor elements are provided. In this method of manufacturing a semiconductor device, first, a base oxide film is formed on a surface of a silicon semiconductor substrate. In the base oxide film, there are formed a thick film portion which is provided along a boundary between the activation region and the element isolation region, having at least a predetermined width from the boundary toward the element isolation region, and a thin film portion thinner than the thick film portion in the activation region and the element isolation region other than the thick film portion. A silicon nitride film is then formed on surfaces of the thick film portion and the thin film portion, and the silicon nitride film in the element isolation region is selectively removed through an over-etching process. It is included that a field oxide film is selectively formed on the surface of the silicon semiconductor substrate in the element isolation region through a field oxidation process using the silicon nitride film in the activation region as a mask.

In this method of manufacturing a semiconductor device, in a case where the silicon nitride film in the element isolation region is selectively removed through an over-etching process using dry etching, a thick film portion of the base oxide film is formed on a side of the element isolation region from a peripheral edge of an etching surface where etching tends to be deep, that is, from a boundary between the activation region and the element isolation region. As a result, even if the thin film portion of the base oxide film is thinned to reduce a bird's beak of the silicon semiconductor substrate, the thick film portion prevents etching from reaching the silicon semiconductor substrate. It is therefore possible to provide a semiconductor device in which large deformation and defects of the field oxide film and a bird's beak thereof are prevented from being generated, and a semiconductor element that can easily obtain desired electrical characteristics can be formed.

It is not practical to directly specify reduction of such local defects in the silicon in the vicinity of the bird's beak.

The term “over-etching” refers to etching capable of sufficiently removing a silicon nitride film that remains due to “in-plane variation” even if just etching is performed. The term “just etching” refers to etching performed until a large part of the silicon nitride film is removed and an etching product in plasma is changed such that a spectrum of plasma light emission is largely changed.

The “base oxide film” refers to a silicon oxide film formed on the surface of the silicon semiconductor substrate (or, for example, a P-type well layer formed on the silicon semiconductor substrate as in the following embodiment), and refers to an oxide film serving as a base of a silicon nitride film used as a mask during field oxidation. The base oxide film is generally formed by using a thermal oxidation method, but may be an oxide film deposited by using CVD. The base oxide film may have any shape as long as it is formed on the silicon semiconductor substrate as a base of the silicon nitride film.

An embodiment of the related art and embodiments of the present invention will be described below in detail with reference to the drawings.

In the drawings, the same constituents are given the same reference numerals, and a repetitive description thereof may be omitted. In the drawings, an X direction, a Y direction, and a Z direction are orthogonal to each other. A direction including the X direction and a direction opposite to the X direction (−X direction) will be referred to as “X-axis direction”, a direction including the Y direction and a direction opposite to the Y direction (−Y direction) will be referred to as a “Y-axis direction”, and a direction including the Z direction and a direction opposite to the Z direction (−Z direction) will be referred to as a “Z-axis direction” (a height direction or a thickness direction). In this regard, in each of the following embodiments, a surface of each film on the Z direction side may be referred to as a “surface”.

The drawings are schematic, and ratios of a width, a length, a depth, and the like are different from those illustrated in the drawings.

First, prior to the description of the embodiments of the present invention, an embodiment of the related art will be described.

Each of these embodiments relates to a method of manufacturing a semiconductor device in which an activation region for forming semiconductor elements and an element isolation region for electrically isolating the semiconductor elements are provided.

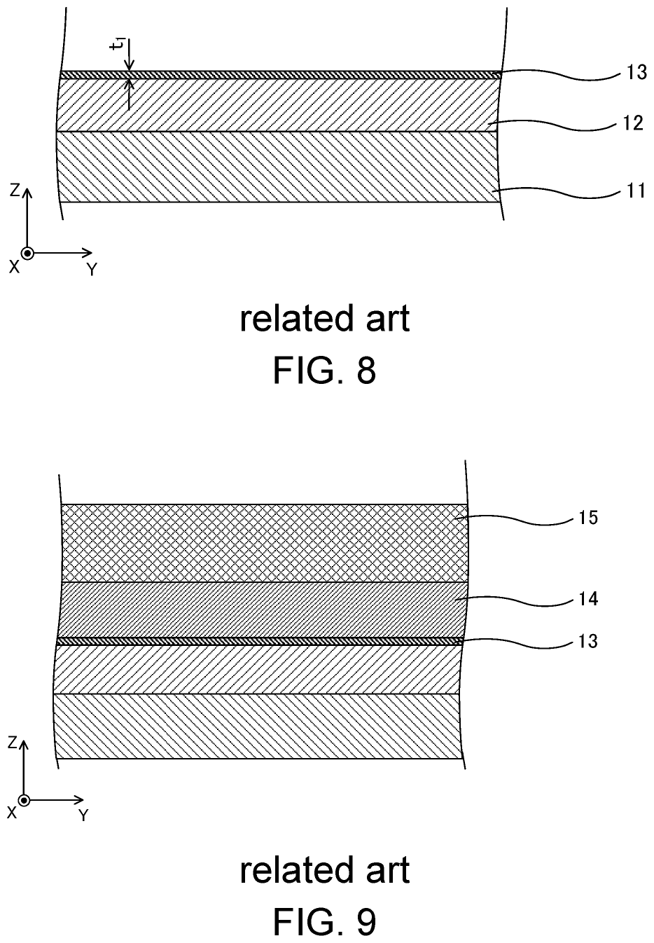

FIGS. 8 to 10 are schematic sectional views illustrating a method of manufacturing a semiconductor device of the related art. In the manufacturing method of the related art illustrated in FIGS. 8 to 10, by making of a base oxide film as thin as possible, it is difficult for an oxidizing species to pass therethrough in the field oxidation, and thus a bird's beak is prevented from becoming large.

As a method of manufacturing a semiconductor device of the related art, first, as illustrated in FIG. 8, a P-type well region 12 is formed on a surface of a P-type silicon semiconductor substrate 11 by implanting and thermally diffusing an impurity, and then a base oxide film 13 having a film thickness t₁ is formed by performing a thermal oxidation process on the P-type well region 12.

As illustrated in FIG. 9, after a silicon nitride film 14 serving as a mask at the time of the field oxidation is formed on the entire surface of the base oxide film 13, a photoresist film 15 serving as a mask at the time of silicon nitride film etching is formed on the entire surface of the silicon nitride film 14.

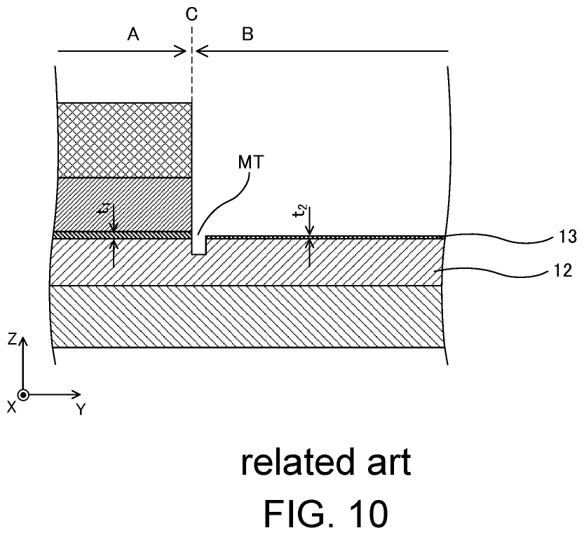

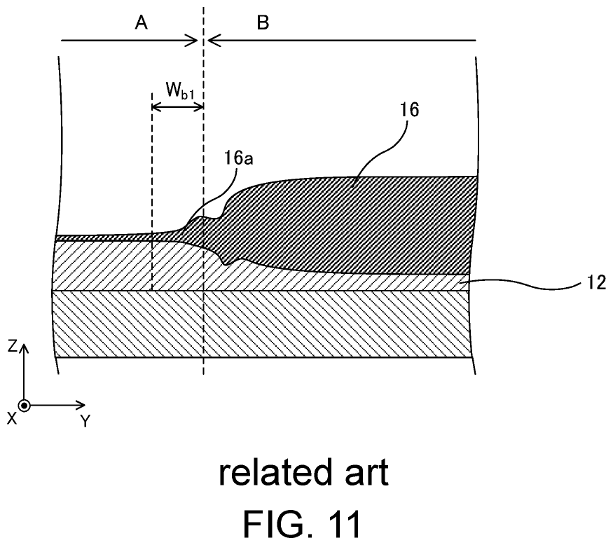

As illustrated in FIG. 10, in an element isolation region B, the photoresist film 15 is selectively removed through an exposure process, and then the silicon nitride film 14 is selectively removed through an etching process.

In the etching process of the silicon nitride film 14, if dry etching is used, a selectivity of the silicon nitride film 14 to the base oxide film 13 becomes relatively small to be on the order of 2 to 3. The silicon nitride film 14 is selectively removed through an over-etching process in consideration of a film thickness variation of the silicon nitride film 14 and an in-plane variation in etching. In this case, an etching surface reaches the base oxide film 13 due to the over-etching process, and the film thickness of the base oxide film 13 becomes t₂ smaller than t₁. On the element isolation region B side from the peripheral edge of the etching surface (that is, a boundary C between an activation region A and the element isolation region B), radicals tend to be accumulated and an etching rate tends to be locally increased, and thus the etching reaches the P-type well region 12 and a micro-trench MT is formed.

In the over-etching process on the silicon nitride film 14, specifically, an etching rate in the vicinity of the peripheral edge of the etching surface may be about 1.2 times higher than an etching rate at a location other than the vicinity of the peripheral edge of the etching surface.

As conditions for an actual over-etching process, the silicon nitride film 14 having a film thickness of 150 nm was selectively removed through dry etching under the condition that an over-etching amount of the base oxide film 13 having a constant film thickness was 10 nm. The base oxide film 13 was then over-etched by about 22 nm in the vicinity of the peripheral edge of the etching surface and by about 10 nm at the location other than the vicinity of the peripheral edge of the etching surface. From this result, assuming that a selectivity of the silicon nitride film 14 to the base oxide film 13 is 2, it is considered that, in terms of the silicon nitride film 14, the silicon nitride film 14 is etched by about 194 nm to 216 nm in the vicinity of the peripheral edge of the etching surface, and etched by about 170 nm to 180 nm at the location other than the vicinity of the peripheral edge of the etching surface. From these values, it can be seen that the etching rate in the vicinity of the peripheral edge of the etching surface is about 1.2 times higher than the etching rate at the location other than the vicinity of the peripheral edge of the etching surface.

Under the conditions of the over-etching process, the width of the region deeply etched from the peripheral edge of the etching surface to the element isolation region B side was about 0.3 μm.

As illustrated in FIG. 10, if the field oxidation is performed in a state in which the micro-trench MT is formed in the P-type well region 12, a surface to which the oxidizing species reacts increases, and thus a formation region W_{b1} of a bird's beak 16a becomes wide, and the field oxide film 16 or the bird's beak 16a is also deformed. There may be thus cases where desired electrical characteristics cannot be obtained in a semiconductor element formed in the activation region A.

It is considered that the micro-trench MT is not formed in the P-type well region 12 by sufficiently increasing of the film thickness of the base oxide film 13.

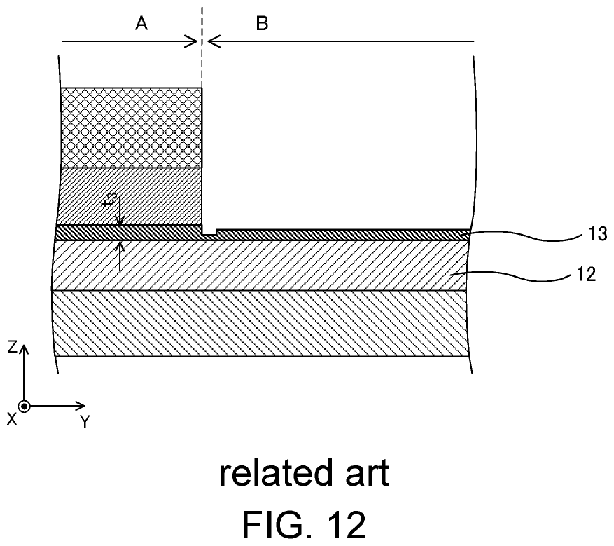

Specifically, as illustrated in FIG. 12, by setting of the film thickness of the base oxide film 13 to t₃ sufficiently larger than t₁, it is possible to prevent the micro-trench MT from being formed in the P-type well regions 12.

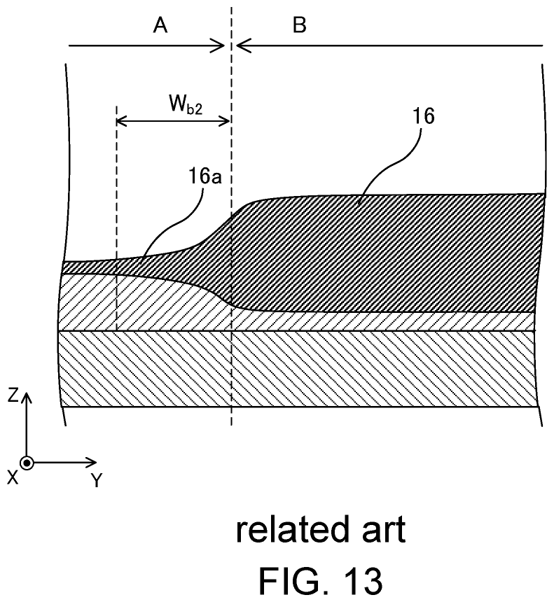

If the field oxidation is performed in this state, as illustrated in FIG. 13, the field oxide film 16 and the bird's beak 16a are not deformed; since the film thickness t₃ of the base oxide film 13 is larger than the film thickness t₁ of the base oxide film 13 illustrated in FIG. 10, the oxidizing species easily passes through the base oxide film 13. As a result, the oxidizing species easily diffuse into the P-type well region 12 under the silicon nitride film 14, and a formation region W_{b2} of the bird's beak 16a becomes wide.

As described above, in the method of manufacturing a semiconductor device of the related art, it is necessary to adjust the film thickness of the base oxide film 13 such that the formation region of the bird's beak 16a is not too wide and the field oxide film 16 and the bird's beak 16a are not deformed; such an adjustment is very difficult.

The embodiments of the present invention provide a semiconductor device capable of forming a semiconductor element 100 that can easily obtain desired electrical characteristics without the field oxide film 16 and the bird's beak 16a being greatly deformed even if the base oxide film 13 is thinned in order to reduce the bird's beak 16a.

### First Embodiment

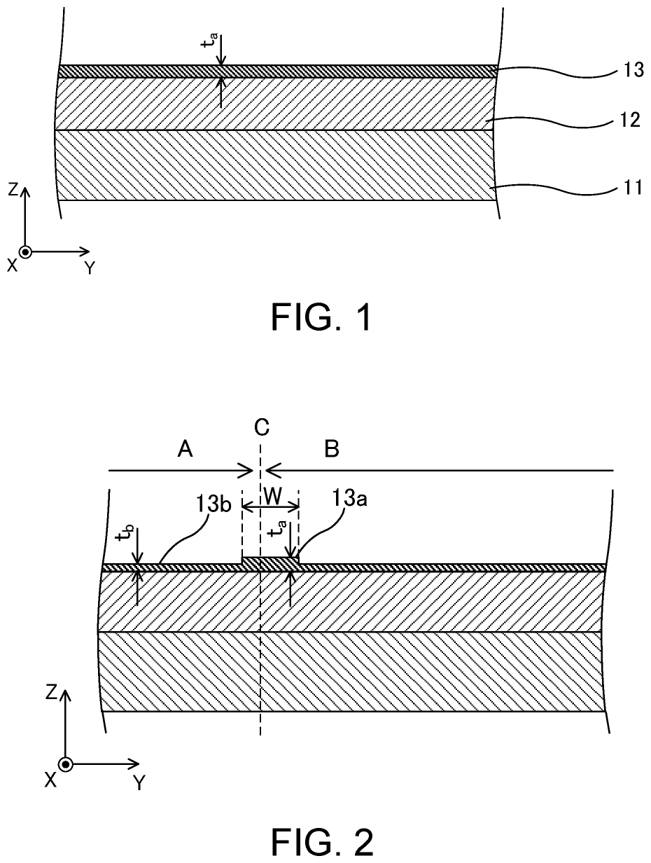

FIGS. 1 to 5 are schematic sectional views illustrating a method of manufacturing a semiconductor device according to a first embodiment.

A semiconductor device 100 according to the first embodiment is manufactured by the method of manufacturing a semiconductor device according to the first embodiment. In the method of manufacturing the semiconductor device according to the first embodiment, an activation region A for forming semiconductor elements and an element isolation region B for electrically isolating the semiconductor elements are provided.

Hereinafter, the method of manufacturing the semiconductor device will be described in detail.

In the method of manufacturing the semiconductor device according to the present embodiment, first, as illustrated in FIG. 1, after a P-type well region 12 is formed on a surface of a P-type silicon semiconductor substrate 11 by implanting and thermally diffusing an impurity, a base oxide film 13 having a film thickness tₐ is formed by performing a thermal oxidation process on the P-type well region 12.

Next, as illustrated in FIG. 2, a thick film portion 13a and a thin film portion 13b are formed on the base oxide film 13.

The thick film portion 13a and the thin film portion 13b are specifically formed by covering with a photoresist film such that a state of a film thickness tₐ is maintained in a range in which the thick film portion 13a is formed, and performing a half-etching process on the base oxide film 13 such that a film thickness is t_{b} smaller than tₐ in a range in which the thin film portion 13b is formed.

The thick film portion 13a is provided along a boundary C between the activation region A and the element isolation region B, and has a predetermined width W at least from the boundary C to the element isolation region B side. The thick film portion 13a functions as a stopper that prevents the silicon nitride film 14 from being over-etched to the P-type well region 12 in a case where the silicon nitride film 14 in the element isolation region B is selectively removed through dry etching. Since an etching rate is locally increased in the vicinity of the peripheral edge of the etching surface where radicals tend to be accumulated, the thick film portion 13a is provided along the boundary C between the activation region A and the element isolation region B so as to include the vicinity of the peripheral edge of the etching surface.

The film thickness tₐ of the thick film portion 13a is not particularly limited as long as it is a film thickness that prevents etching from reaching the P-type well region 12 in a case where the silicon nitride film 14 is selectively removed, and may be selected as appropriate according to purposes. It is preferable that the film thickness tₐ is thin enough for the etching not to reach the P-type well region 12 from the viewpoint that if the film thickness is too large, the bird's beak formation region is easily expanded.

The predetermined width W of the thick film portion 13a is not particularly limited as long as it is equal to or larger than a width to be deeply etched in the vicinity of the peripheral edge of the etching surface in a case where the silicon nitride film 14 is selectively removed, and may be selected as appropriate according to purposes, but a width to be etched deeply in the vicinity of the peripheral edge of the etching surface is preferable.

In the present embodiment, the predetermined width W of the thick film portion 13a is set to 1 μm from the viewpoint that the thick film portion 13a can be stably formed along the boundary C between the activation region A and the element isolation region B.

A position of the thick film portion 13a is not particularly limited as long as it can be provided along the boundary C between the activation region A and the element isolation region B so as to include a region to be deeply etched in the vicinity of the peripheral edge of the etching surface, and may be selected as appropriate according to purposes; however, a position including a width to be deeply etched in the element isolation region B is preferable. From the viewpoint of reducing a bird's beak, it is preferable that the thick film portion 13a is not included in the activation region A.

In the present embodiment, the position of the thick film portion 13a is a position in which 0.3 μm of 1 μm of the predetermined width W of the thick film portion 13a is included in the activation region A and 0.7 μm is included in the element isolation region B.

The thin film portion 13b has a film thickness t_{b} smaller than the film thickness tₐ of the thick film portion 13a in the activation region A and the element isolation region B other than the thick film portion 13a.

The film thickness t_{b} of the thin film portion 13b is not particularly limited as long as it is a film thickness that prevents the etching from reaching the P-type well region 12 in a case where the silicon nitride film 14 is selectively removed, and may be selected as appropriate according to purposes; however, the thickness t_{b} is preferably smaller, for example, 35 nm or less in that the oxidizing species does not easily pass through the thin film portion 13b during the field oxidation and the thin film portion 13b can be prevented from diffusing under the silicon nitride film 14. The film thickness t_{b} of the thin film portion 13b is preferably 20 nm or more in that, if the thin film portion 13b is too thin, dislocation occurs in the silicon semiconductor substrate 11 due to stress and thus a durable period of the silicon semiconductor substrate 11 tends to be reduced.

Considering the film thicknesses of the thick film portion 13a and the thin film portion 13b from the film thickness of the silicon nitride film 14, a case will be considered where the silicon nitride film 14 is removed through etching 1.2 times deeper than the film thickness t of the silicon nitride film 14 in order to completely selectively remove the silicon nitride film 14. In this case, assuming that a selectivity of the silicon nitride film 14 to the base oxide film 13 is estimated by 2 to be rather small, the thin film portion 13b of the base oxide film 13 is etched to a film thickness of 0.1t. The film thickness t_{b} of the thin film portion 13b needs to be 0.1t or more. In the vicinity of the peripheral edge of the etching surface, since the etching is performed as deep as 1.2 times the film thickness of the thin film portion 13b, the thick film portion 13a of the base oxide film 13 is etched to a film thickness of 0.22t. The film thickness tₐ of the thick film portion 13a needs to be 0.22t or more.

Specifically, assuming that the selectivity of the silicon nitride film 14 to the base oxide film 13 is 2, it is preferable to satisfy the following expression: (t+2tₐ)/(t+2t_{b})≥1.2.

For example, if the film thickness t of the silicon nitride film 14 is 150 nm, the film thickness t_{b} of the thin film portion 13b is 0.1t or more, the film thickness tₐ of the thick film portion 13a is 0.22t or more, and considering that a preferable range of the film thickness t_{b} of the thin film portion 13b is 20 nm≤t_{b}≤35 nm, the film thickness tₐ of the thick film portion 13a is 39 nm or more, and the film thickness t_{b} of the thin film portion 13b is 20 nm or more.

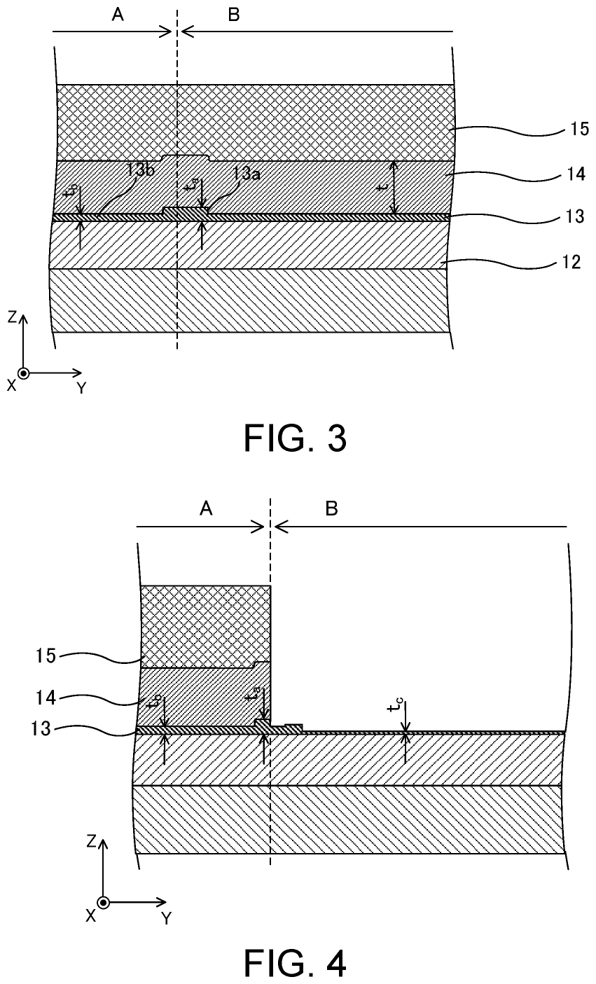

Next, as illustrated in FIG. 3, after a silicon nitride film 14 is formed on the entire surface of the base oxide film 13 including the thick film portion 13a and the thin film portion 13b according to a CVD method, a photoresist film 15 is formed on the entire surface of the silicon nitride film 14.

The film thickness of the silicon nitride film 14 is not particularly limited as long as there is a film thickness to be served as a mask in a case where the field oxidation is performed, and may be selected as appropriate according to purposes; however, the film thickness is preferable at which the silicon nitride film 14 can be easily selected and removed.

In the present embodiment, the film thickness t of the silicon nitride film 14 is set to 150 nm.

As illustrated in FIG. 4, after the photoresist film 15 in the element isolation region B is selectively removed through an exposure process, the silicon nitride film 14 in the element isolation region B is selectively removed through an over-etching process using dry etching. In this case, a film thickness t_{c} of the base oxide film 13 of the etching surface becomes smaller than the film thickness to of the thick film portion 13a and the film thickness t_{b} of the thin film portion 13b.

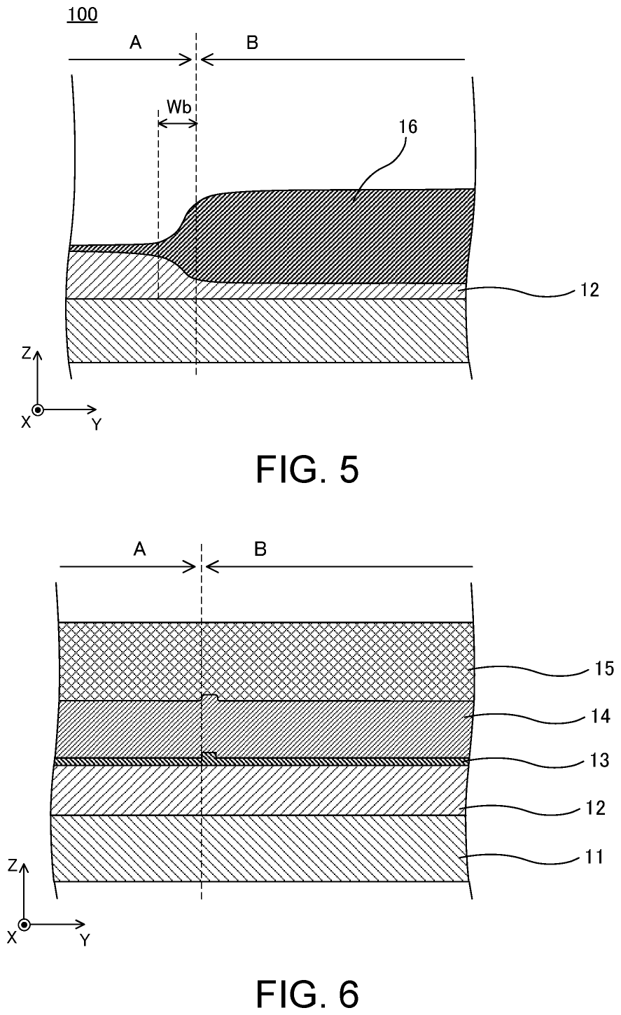

As illustrated in FIG. 5, a field oxide film 16 is selectively formed on the surface of the P-type well region 12 in the element isolation region B through the field oxidation process using the silicon nitride film 14 in the activation region A illustrated in FIG. 4 as a mask.

After the field oxide film 16 is formed, the silicon nitride film 14 and the base oxide film 13 in the activation region A are removed, and a semiconductor element such as a MOSFET is formed in the activation region A.

As described above, in the method of manufacturing the semiconductor device according to the first embodiment, the etching does not reach the P-type well region 12, so that the micro-trench MT does not occur. In this method of manufacturing a semiconductor device, it is possible to form the semiconductor element that can easily obtain desired electrical characteristics by suppressing of the occurrence of large deformation or defects of the field oxide film 16 and the bird's beak 16a even if the base oxide film 13 is thinned in order to reduce the bird's beak 16a.

### Second Embodiment

FIG. 6 is a schematic sectional view illustrating a method of manufacturing a semiconductor device according to a second embodiment. FIG. 6 illustrates a state similar to the state in which the photoresist film 15 illustrated in FIG. 3 is formed in the first embodiment.

As illustrated in FIG. 6, the second embodiment is the same as the first embodiment except that the thick film portion 13a in the first embodiment is not formed to extend to the activation region A.

As a result, in the second embodiment, since the thick film portion 13a is not formed to extend to the activation region A, the oxidizing species hardly passes under the silicon nitride film 14 in the activation region A at the time of field oxidation, and thus the bird's beak can be made smaller.

### Third Embodiment

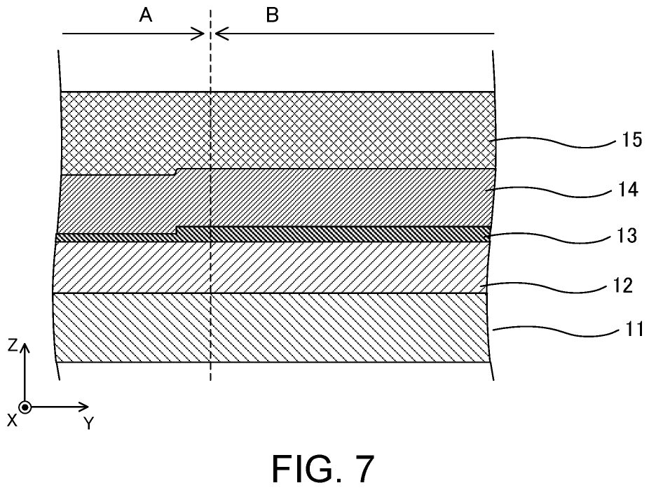

FIG. 7 is a schematic sectional view illustrating a method of manufacturing a semiconductor device in a third embodiment. FIG. 7 illustrates a state similar to the state in which the photoresist film 15 illustrated in FIG. 3 is formed in the first embodiment.

As illustrated in FIG. 7, the third embodiment is the same as the first embodiment except that the thick film portion 13a in the first embodiment is formed to extend over the entire region of the element isolation region B.

As a result, in the third embodiment, since the thick film portion 13a is formed to extend over the entire region of the element isolation region B, it is possible to easily perform an alignment in a case where an exposure process on the photoresist film 15 and an over-etching process on the silicon nitride film 14 are performed.

As described above, the method of manufacturing a semiconductor device according to the embodiment of the present invention is a method of manufacturing a semiconductor device in which an activation region for forming semiconductor elements and an element isolation region for electrically isolating the semiconductor elements are provided. In this method of manufacturing a semiconductor device, first, a base oxide film is formed on a surface of a silicon semiconductor substrate. In the base oxide film, there are formed a thick film portion which is provided along a boundary between the activation region and the element isolation region, having at least a predetermined width from the boundary toward the element isolation region, and a thin film portion thinner than the thick film portion in the activation region and the element isolation region other than the thick film portion. A silicon nitride film is then formed on surfaces of the thick film portion and the thin film portion, and the silicon nitride film in the element isolation region is selectively removed through an over-etching process. It is included that a field oxide film is selectively formed on the surface of the silicon semiconductor substrate in the element isolation region through a field oxidation process using the silicon nitride film in the activation region as a mask.

As a result, it is possible to provide a semiconductor device capable of forming a semiconductor element that can easily obtain desired electrical characteristics by suppressing of the occurrence of large deformation or defects of a field oxide film and a bird's beak thereof even if a base oxide film is thinned in order to reduce the bird's beak.

Although the embodiments of the present invention have been specifically described above, the present invention is not limited to the embodiments described above, and may be variously modified without departing from the concept thereof.

For example, in each of the embodiments described above, the P-type well region is formed on the P-type silicon semiconductor substrate, but the present invention is not limited to this; both may be of the N-type or one of both may be of the N-type.

In each of the above embodiments described, the P-type well region is formed, but the present invention is not limited thereto, and the P-type well region does not have to be formed.

In each of the above embodiments, the thick film portion and the thin film portion are formed through the half-etching process, but the present invention is not limited to this, and the thick film portion may be formed through a field oxidation process.

What is claimed is:

1. A method of manufacturing a semiconductor device in which an activation region for forming semiconductor elements and an element isolation region for electrically isolating the semiconductor elements are provided, the method comprising:
forming a base oxide film on a surface of a silicon semiconductor substrate;
forming a thick film portion provided along a boundary between the activation region and the element isolation region and having at least a predetermined width from the boundary toward the element isolation region and a thin film portion thinner than the thick film portion in the activation region and the element isolation region other than the thick film portion on the base oxide film;
forming a silicon nitride film on surfaces of the thick film portion and the thin film portion;
selectively removing the silicon nitride film in the element isolation region through an over-etching process; and
selectively forming a field oxide film on the surface of the silicon semiconductor substrate in the element isolation region through a field oxidation process using the silicon nitride film in the activation region as a mask.

2. The method of manufacturing a semiconductor device according to claim 1, wherein
the predetermined width is set by measuring in advance a width of a region deeply etched from the boundary toward the element isolation region in the base oxide film having a constant film thickness under a condition of the over-etching process for selectively removing the silicon nitride film.

3. The method of manufacturing a semiconductor device according to claim 1, wherein
the thick film portion is formed to extend toward the activation region in the over-etching process on the silicon nitride film.

4. The method of manufacturing a semiconductor device according to claim 2, wherein
the thick film portion is formed to extend toward the activation region in the over-etching process on the silicon nitride film.

5. The method of manufacturing a semiconductor device according to claim 1, wherein
the thick film portion is formed in the entire region of the element isolation region in the over-etching process on the silicon nitride film.

6. The method of manufacturing a semiconductor device according to claim 2, wherein
the thick film portion is formed in the entire region of the element isolation region in the over-etching process on the silicon nitride film.

7. The method of manufacturing a semiconductor device according to claim 3, wherein
the thick film portion is formed in the entire region of the element isolation region in the over-etching process on the silicon nitride film.

8. The method of manufacturing a semiconductor device according to claim 4, wherein
the thick film portion is formed in the entire region of the element isolation region in the over-etching process on the silicon nitride film.

9. The method of manufacturing a semiconductor device according to claim 1, wherein
the thick film portion and the thin film portion are formed through a half-etching process.

10. The method of manufacturing a semiconductor device according to claim 1, wherein
the thick film portion and the thin film portion are formed through the field oxidation process.

11. A semiconductor device manufactured by the method of manufacturing a semiconductor device according to claim 1.
